(19) United States
(12) Patent Application Publication
(10) Pub. No.: US 2024/0047180 A1
(43) Pub. Date: Feb. 8, 2024

(54) SUBSTRATE PROCESSING APPARATUS, METHOD OF PROCESSING SUBSTRATE, METHOD OF MANUFACTURING SEMICONDUCTOR DEVICE AND RECORDING MEDIUM

(71) Applicant: Kokusai Electric Corporation, Tokyo (JP)

(72) Inventors: Daisuke HARA, Toyama-shi (JP); Takashi YAHATA, Toyama-shi (JP); Tsuyoshi TAKEDA, Toyama-shi (JP)

(73) Assignee: Kokusai Electric Corporation, Tokyo (JP)

(21) Appl. No.: 18/025,621

(22) PCT Filed: Sep. 9, 2021
(86) PCT No.: PCT/JP2021/033095

§ 371 Date: Mar. 9, 2023

(30) Foreign Application Priority Data
Sep. 10, 2020 (JP) 2020-152432

(51) Int. Cl. H01J 37/32

(52) U.S. Cl. CPC H01J 37/32669; H01J 37/32743; H01J 2237/3387

(57) ABSTRACT

There is provided a technique that includes a process chamber in which a substrate is processed, a substrate retainer on which a plurality of substrates are stacked in multiple stages, a plasma generator generating plasma inside the process chamber, and a magnet generating a magnetic field inside the process chamber.

### BACKGROUND

### 1. Field

This present disclosure relates to a substrate processing apparatus, a method for manufacturing a semiconductor device, and a program.

### 2. Description of the Related Art

In one manufacturing step of a semiconductor device, raw material gas, reactant gas, or the like may be activated by plasma and supplied to a substrate that is carried into a process chamber of a substrate processing apparatus, and substrate processing of forming various films such as an insulation film, a semiconductor film, or a conductor film on the substrate or removing various films may be performed. For example, a buffer chamber generating plasma inside a reaction tube is provided.

### SUMMARY

The present disclosure is to provide a technique that is capable of supplying plasma active species gas generated at a high efficiency to a substrate.

According to one embodiment of the present disclosure, there is provided a technique that includes a process chamber in which a substrate is processed, a substrate retainer on which a plurality of substrates are stacked in multiple stages, a plasma generator generating plasma inside the process chamber, and a magnet generating a magnetic field inside the process chamber.

### BRIEF DESCRIPTION OF DRAWINGS

FIG. 1 is a schematic configuration diagram of a vertical processing furnace of a substrate processing apparatus that is preferably used in an embodiment of the present disclosure, and is a longitudinal sectional view of the processing furnace.

FIG. 2 is a schematic configuration diagram of the vertical processing furnace of the substrate processing apparatus that is preferably used in the embodiment of the present disclosure, and is a sectional view of the processing furnace taken along line A-A in FIG. 1.

FIG. 3A is an enlarged transverse sectional view for describing a buffer structure of the substrate processing apparatus that is preferably used in the embodiment of the present disclosure. FIG. 3B is a schematic diagram for describing the buffer structure of the substrate processing apparatus that is preferably used in the embodiment of the present disclosure.

FIG. 4 is a schematic configuration diagram of a controller of the substrate processing apparatus that is preferably used in the embodiment of the present disclosure, and is a block diagram of a control system of the controller.

FIG. 5 is a flowchart of a substrate processing step according to the embodiment of the present disclosure.

FIG. 6A is a front view of a heat insulating plate including a magnet that is preferably used in the embodiment of the present disclosure, and FIG. 6B is a schematic diagram describing a magnetic field according to the magnet illustrated in FIG. 6A.

FIG. 7 is a schematic configuration diagram of a vertical processing furnace of a substrate processing apparatus that is preferably used in other embodiments of the present disclosure, and is the same sectional view as FIG. 2.

### DETAILED DESCRIPTION

<Embodiments of Present Disclosure>

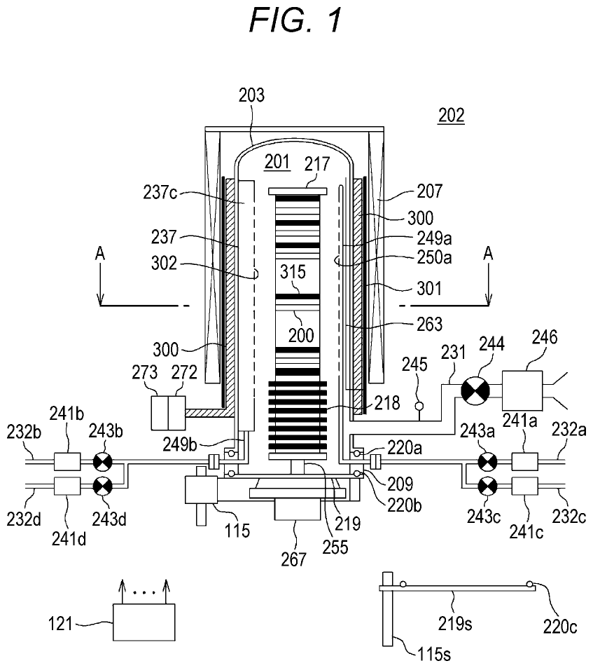

Hereinafter, one embodiment of the present disclosure will be mainly described with reference to FIG. 1 to FIG. 7. Furthermore, all of the diagrams used in the following description are schematic, and dimensional relationships between elements, ratios between the elements, and the like illustrated in the diagrams do not necessarily match actual ones. The dimensional relationships between elements, the ratios between the elements, and the like do not necessarily match between a plurality of diagrams.

(1) Configuration of Substrate Processing Apparatus

(Heater)

As illustrated in FIG. 1, a processing furnace 202 that is used in a substrate processing apparatus is a so-called vertical furnace that is capable of containing substrates in a vertical direction in multiple stages, and includes a heater 207 serving as a heater (a heating mechanism). The heater 207 has a cylindrical shape, and is vertically installed by being supported by a heater base (not illustrated) as a holding plate. The heater 207 also functions as an activation mechanism (an exciter) that activates (excites) gas with heat as described below.

(Process Chamber)

Inside the heater 207, a reaction tube 203 is provided concentrically with the heater 207. The reaction tube 203, for example, is formed of a heat-resistant material such as quartz (SiO2) or silicon carbide (SiC), and is formed into a cylindrical shape in which an upper end is closed and a lower end is opened. A manifold (an inlet flange) 209 is arranged concentrically with the reaction tube 203 below the reaction tube 203. The manifold 209, for example, is formed of a metal such as stainless steel (SUS), and is formed into a cylindrical shape in which an upper end and a lower end are opened. The upper end of the manifold 209 engages the lower end of the reaction tube 203, and is configured to support the reaction tube 203. An O-ring 220a serving as a seal member is provided between the manifold 209 and the reaction tube 203. The manifold 209 is supported by a heater base, and thus, the reaction tube 203 is vertically installed. A processing container (a reaction container) is mainly configured by the reaction tube 203 and the manifold 209. A process chamber 201 is formed in a cylindrical hollow portion that is the inside of the processing container. The process chamber 201 is configured to be capable of containing a plurality of wafers 200 serving as the substrate, and a plurality of heat insulating plates 315 described below, in which the wafer 200 and the heat insulating plate 315 are alternately disposed. However, the processing container is not limited to the configuration described above, and the reaction tube 203 may be referred to as the processing container.

In the process chamber 201, a nozzle 249a and piping 249b are provided to penetrate through a side wall of the manifold 209. Gas supply pipes 232a and 232b are connected to the nozzle 249a and the piping 249b, respectively. As described above, one nozzle 249a, one piping 249b, and two gas supply pipes 232a and 232b are provided in the process chamber 201, and a plurality of types of gas can be supplied into the process chamber 201.

In the gas supply pipes 232a and 232b, mass flow controllers (MFCs) 241a and 241b that are flow rate controllers and valves 243a and 243b that are opening/closing valves are provided in this order from the upstream side of the gas flow. Gas supply pipes 232c and 232d that supply inert gas are connected to the downstream sides of the valves 243a and 243b of the gas supply pipes 232a and 232b, respectively. In the gas supply pipes 232c and 232d, MFCs 241c and 241d and valves 243c and 243d are provided in this order from the upstream side of the gas flow, respectively.

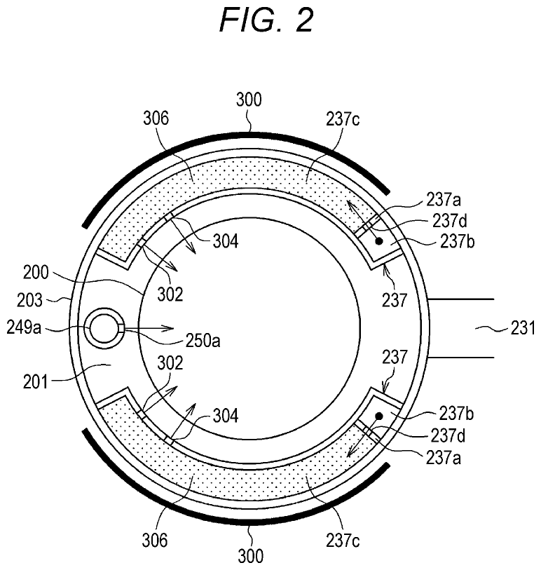

As illustrated in FIG. 2, the nozzle 249a is provided to rise toward an upper side in a stacking direction of the wafer 200, in a space between an inner wall of the reaction tube 203 and the wafer 200 along an upper portion from a lower portion of the inner wall of the reaction tube 203. That is, the nozzle 249a is provided to follow a wafer arrangement region (a mounting region) in which the wafer 200 is arranged (mounted), in a region horizontally surrounding the wafer arrangement region on the lateral of the wafer arrangement region. That is, the nozzle 249a is provided in a direction vertical to the surface (a flat surface) of the wafer 200 on the lateral of an end portion (a peripheral portion) of each of the wafers 200 carried into the process chamber 201. A gas supply hole 250a that supplies gas is provided on a lateral surface of the nozzle 249a. The gas supply hole 250a is opened to be directed toward the center of the reaction tube 203, and gas can be supplied toward the wafer 200. A plurality of gas supply holes 250a are provided from the lower portion to the upper portion of the reaction tube 203, and each of the gas supply holes has the same opening area and is provided at the same opening pitch.

The piping 249b is connected to a distal end portion of the gas supply pipe 232b. The piping 249b is connected into a buffer structure 237. In this embodiment, in plan view, two buffer structures 237 are disposed to interpose a straight line passing through the center of the reaction tube 203 (the process chamber 201) and the nozzle 249a or is disposed to interpose a straight line passing through the center of the reaction tube 203 and an exhaust pipe (an exhauster) 231, and two buffer structures 237 are disposed symmetrically to a line connecting the nozzle 249a and the exhaust pipe 231. A partition plate 237a is provided in the buffer structure 237, and a gas introduction area 237b that introduces gas from the piping 249b and a plasma area 237c in which gas is formed into plasma are partitioned by the partition plate 237a. The plasma area 237c is also referred to as a buffer chamber 237c that is a gas distribution space. The buffer chamber 237c is disposed on the nozzle 249a side, and the gas introduction area 237b is disposed on the exhaust pipe 231 side.

As illustrated in FIG. 2, the buffer chamber 237c is provided in an annular space between the inner wall of the reaction tube 203 and the wafer 200 in plan view, and in a portion from the lower portion to the upper portion of the inner wall of the reaction tube 203, along the stacking direction of the wafer 200. That is, the buffer chamber 237c is formed by the buffer structure 237 to follow the wafer arrangement region, in the region horizontally surrounding the wafer arrangement region on the lateral of the wafer arrangement region. The buffer structure 237 is formed of an insulator that is a heat-resistant material such as quartz or SiC, and gas supply ports 302 and 304 that supply gas are formed in an arc-shaped wall surface of the buffer structure 237. A plurality of gas supply ports 302 and 304 are provided in a horizontal direction of the plurality of wafers 200 that are stacked, and are opened to be directed toward the center of the reaction tube 203, and gas can be supplied toward the wafer 200. The plurality of gas supply ports 302 and 304 are provided along the stacking direction of the wafer 200 from the lower portion to the upper portion of the reaction tube 203, and each of the gas supply ports has the same opening area and is provided at the same opening pitch.

The gas introduction area 237b is provided to rise toward the upper side in the stacking direction of the wafer 200, along the upper portion from the lower portion of the inner wall of the reaction tube 203. A gas supply hole 237d that supplies gas to the plasma area 237c from the gas introduction area 237b is provided in the partition plate 237a. Accordingly, reactant gas supplied to the gas introduction area 237b is distributed inside the buffer chamber 237c. As with the gas supply hole 250a, a plurality of gas supply holes 237d are provided from the lower portion to the upper portion of the reaction tube 203. In addition, instead of the piping 249b and the gas introduction area 237b, a nozzle, for example, a porous nozzle similar to the nozzle 249a may be provided inside the buffer chamber 237c to supply processing gas.

As described above, in this embodiment, gas is transferred through the nozzle 249a and the buffer chamber 237c disposed inside an annular vertical space which is defined by an inner wall of a side wall of the reaction tube 203 and the end portion of the plurality of wafers 200 arranged inside the reaction tube 203, that is, inside a cylindrical space in planar view. In the vicinity of the wafer 200, gas is ejected first into the reaction tube 203 from the gas supply hole 250a and the gas supply ports 302 and 304 that are opened to the nozzle 249a and the buffer chamber 237c, respectively. A main flow of the gas inside the reaction tube 203 is in a direction parallel to the surface of the wafer 200, that is, the horizontal direction. According to such a configuration, gas can be uniformly supplied to each of the wafers 200, and the uniformity of a film thickness of a film to be formed on each of the wafers 200 can be improved. The gas that has flowed on the surface of the wafer 200, that is, the remaining gas after the reaction flows towards the direction of an exhaust port, that is, the exhaust pipe 231 described below. Here, the direction of the flow of the remaining gas is suitably specified by the position of the exhaust port, and is not limited to the vertical direction.

As a raw material containing a predetermined element, for example, silane raw material gas containing silicon (Si) serving as a predetermined element is supplied into the process chamber 201 from the gas supply pipe 232a through the MFC 241a, the valve 243a, and the nozzle 249a.

The raw material gas is a raw material in a gas state, for example, gas that is obtained by vaporizing a raw material in a liquid state under ordinary temperatures and pressures, a raw material that is in a gas state under ordinary temperatures and pressures, or the like. In the present specification, in the case of using the term “raw material”, the term “raw material” may mean a “liquid material in a liquid state”, may mean “raw material gas in a gas state”, or may mean both thereof.

As the silane raw material gas, for example, raw material gas containing Si and a halogen element, that is, halosilane raw material gas can be used. The halosilane raw material is a silane raw material having a halogen group. The halogen element includes at least one selected from the group consisting of chlorine (Cl), fluorine (F), bromine (Br), and iodine (I). That is, the halosilane raw material has at least one halogen group selected from the group consisting of a chloro group, a fluoro group, a bromo group, and an iodine group. It can be said that the halosilane raw material is one type of halide.

As the halosilane raw material gas, for example, raw material gas containing Si and Cl, that is, chlorosilane raw material gas can be used. As the chlorosilane raw material gas, for example, dichlorosilane (SiH2Cl2, Abbreviated Name: DCS) gas can be used.

As a reactant (a reactant) containing an element different from the predetermined element described above, for example, nitrogen (N)-containing gas serving as reactant gas is supplied into the buffer chamber 237c from the gas supply pipe 232b through the MFC 241b, the valve 243b, the piping 249b, and the gas introduction area 237b. As the N-containing gas, for example, hydronitrogen-based gas can be used. It can be said that the hydronitrogen-based gas is a substance containing two elements of N and H, and the hydronitrogen-based gas functions as nitridation gas, that is, an N source. As the hydronitrogen-based gas, for example, ammonia (NH3) gas can be used.

As inert gas, for example, nitrogen (N2) gas is supplied into the process chamber 201 from the gas supply pipes 232c and 232d through each of the MFCs 241c and 241d, the valves 243c and 243d, the gas supply pipes 232a and 232b, the nozzle 249a, and the piping 249b.

A raw material supply system serving as a first gas supply system is mainly formed by the gas supply pipe 232a, the MFC 241a, and the valve 243a. A reactant supply system (a reactant supply system) serving as a second gas supply system is mainly formed by the gas supply pipe 232b, the MFC 241b, and the valve 243b. An inert gas supply system is mainly formed by the gas supply pipes 232c and 232d, the MFCs 241c and 241d, and the valves 243c and 243d. The raw material supply system, the reactant supply system, and the inert gas supply system are also collectively referred to simply as a gas supply system (a gas supplier).

(Plasma Generator)

Next, a plasma generator will be described by using FIG. 1 to FIGS. 3A and 3B.

As illustrated in FIG. 2, capacitively coupled plasma (Abbreviated Name: CCP) is used as plasma, and is generated by the buffer structure 237 inside the reaction tube 203 (the process chamber 201) that is a vacuum partition wall formed of quartz or the like when supplying the reactant gas.

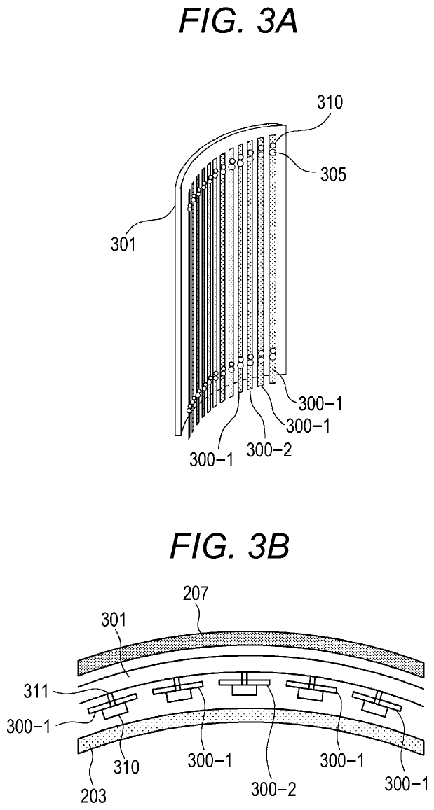

As illustrated in FIG. 2 and FIG. 3A, an external electrode 300 is formed of a thin plate having a rectangular shape that is long in an arrangement direction of the wafer 200. As illustrated in FIG. 1 and FIG. 3B, in the external electrode 300, a first external electrode (a Hot electrode) 300-1 to which a high-frequency power supply 273 is connected through a matching box 272, and a second external electrode (a Ground electrode) 300-2 grounded to the earth in which a reference potential is 0 V are disposed at an equal interval. In the present disclosure, in a case where there is no need to particularly perform the description distinctively, the external electrodes will be described as the external electrode 300.

The external electrode 300 is provided outside the process chamber 201 corresponding to a position at which the buffer structure 237 is provided, between the reaction tube 203 and the heater 207. Specifically, in the buffer structure, the plasma area (the buffer chamber) 237c is provided as an area for forming gas into plasma, and the external electrode 300 is disposed approximately into the shape of an arc to follow an outer wall of the reaction tube 203 (the outside of the process chamber 201) corresponding to a position at which the buffer chamber 237c is provided. The external electrode 300, for example, is disposed by being fixed to an inner wall surface of a quartz cover that is formed into the shape of an arc at a center angle of 30 degrees or more and 240 degrees or less. That is, the external electrode 300 is disposed on an outer circumference of the reaction tube 203 corresponding to the position at which the buffer chamber 237c is provided. In addition, in the buffer structure 237, the gas supplier (the gas introduction area) 237b is provided as an area for supplying gas to the buffer chamber 237c. The external electrode 300 is not provided on the outer circumference of the reaction tube 203 corresponding to a position at which the gas introduction area 237b is provided. For example, a high frequency of 13.56 MHz is input to the external electrode 300 from the high-frequency power supply 273 through the matching box 272, and thus, plasma active species 306 are generated inside the buffer chamber 237c. According to the plasma generated as described above, the plasma active species 306 for substrate processing can be supplied to the surface of the wafer 200 from around the wafer 200. The plasma generator is mainly formed by the buffer structure 237, the external electrode 300, and the high-frequency power supply 273. The plasma generator is provided outside the process chamber 201.

The external electrode 300 can be formed of a metal such as aluminum, copper, and stainless steel, and by forming the external electrode with an oxidation-resistant material such as nickel, it is possible to perform the substrate processing while suppressing the degradation of electric conductivity. In particular, by forming the external electrode with a nickel-alloy material to which aluminum is added, an AlO film that is an oxide film having high heat resistance and high corrosion resistance is formed on the surface of the electrode. According to an effect of forming such a film, it is possible to suppress the progress of the degradation inside the electrode, and thus, it is possible to suppress a decrease in a plasma generation efficiency due to a decrease in the electric conductivity.

(Electrode Fixing Jig)

Next, a quartz cover 301 serving as an electrode fixing jig that fixes the external electrode 300 will be described by using FIGS. 3A and 3B. As illustrated in FIGS. 3A and 3B, a plurality of external electrodes 300 are fixed by hooking and sliding a cutout (not illustrated) to a protrusion 310 provided on the inner wall surface of the quartz cover 301 that is a curved electrode fixing jig to be installed on the outer circumference of the reaction tube 203 as a unit (a hook type electrode unit) integrated with the quartz cover 301. Here, such a unit is referred to as an electrode fixing unit including the external electrode 300 and the quartz cover 301 that is the electrode fixing jig. In addition, quartz and a nickel alloy are adopted as the materials of the quartz cover 301 and the external electrode 300, respectively.

In order to obtain high processing capability at a substrate temperature of 500° C. or lower, it is desirable that the quartz cover 301 is in the shape of an arc having a center angle of 30 degrees or more and 240 degrees or less, and is disposed to avoid the exhaust pipe 231, the nozzle 249a, and the like, which are an exhaust port for avoiding the generation of particles. In a case where the quartz cover is configured to have a center angle less than 30 degrees, the number of external electrodes 300 to be disposed decreases, and the amount of production of plasma decreases. In a case where the quartz cover is configured to have a center angle greater than 240 degrees, the area of a lateral surface of the reaction tube 203 that is covered with the quartz cover 301 excessively increases, and heat energy from the heater 207 is blocked. In this embodiment, two quartz covers having a center angle of 110 degrees are symmetrically disposed.

The exhaust pipe 231 serving as an exhauster that exhausts an atmosphere inside the process chamber 201 is provided in the reaction tube 203. A vacuum pump 246 serving as a vacuum exhaust is connected to the exhaust pipe 231 through a pressure sensor 245 serving as a pressure detector (a pressure detector) that detects a pressure inside the process chamber 201 and an auto pressure controller (APC) valve 244 serving as an exhaust valve (a pressure regulator). The APC valve 244 is a valve configured to be capable of performing vacuum exhaust and stopping the vacuum exhaust inside the process chamber 201 by opening/closing a valve in a state where the vacuum pump 246 is operated, and to be capable of regulating the pressure inside the process chamber 201 by adjusting the degree of valve opening, on the basis of pressure information that is detected by the pressure sensor 245, in a state where the vacuum pump 246 is operated An exhaust system is mainly formed by the exhaust pipe 231, the APC valve 244, and the pressure sensor 245. The vacuum pump 246 may be considered to be included in the exhaust system. The exhaust pipe 231 is not limited to a case where the exhaust pipe is provided in the reaction tube 203, and may be provided in the manifold 209 as with nozzle 249a.

Below the manifold 209, a seal cap 219 serving as a furnace opening lid capable of hermetically closing the lower end opening of the manifold 209 is provided. The seal cap 219 is configured to abut against a lower end of the manifold 209 from a lower side in the vertical direction. The seal cap 219, for example, is formed of a metal such as SUS, and is formed into the shape of a disk. An O-ring 220b serving as a seal member in contact with the lower end of the manifold 209 is provided on the upper surface of the seal cap 219. On a side of the seal cap 219 opposite to the process chamber 201, a rotation mechanism 267 that rotates a boat 217 described later is disposed. A rotation shaft 255 of the rotation mechanism 267 penetrates the seal cap 219 and is connected to the boat 217. The rotation mechanism 267 is configured to rotate the wafer 200 by rotating the boat 217. The seal cap 219 is configured to be raised and lowered in the vertical direction by a boat elevator 115 serving as a raising/lowering mechanism vertically disposed outside the reaction tube 203. The boat elevator 115 is configured to be able to load the boat 217 into the process chamber 201 and unload the boat 217 out of the process chamber 201 by raising and lowering the seal cap 219. The boat elevator 115 is configured as a transfer device (a transfer mechanism) that transfers the boat 217, that is, the wafer 200 to the inside and the outside of the process chamber 201. In addition, a shutter 219s serving as a furnace opening lid that is capable of hermetically closing a lower end opening of the manifold 209 while the seal cap 219 is lifted down by the boat elevator 115 is provided below the manifold 209. The shutter 219s, for example, is formed of a metal such as SUS, and is formed into the shape of a disk. An O-ring 220c serving as a seal member that abuts against the lower end of the manifold 209 is provided on an upper surface of the shutter 219s. An opening/closing operation (a lifting operation, a turning operation, or the like) of the shutter 219s is controlled by a shutter opening/closing mechanism 115s.

(Substrate Support)

As illustrated in FIG. 1, the boat 217 serving as a substrate support (a substrate retainer and a substrate retainer) is configured to support a plurality of, for example, 25 to 200 wafers 200 and heat insulating plates 315 described below in multiple stages by aligning the wafers and the heat insulating plates in a horizontal attitude and in the vertical direction in the state being centered on each other, that is, to arrange the wafers and the heat insulating plates at a predetermined interval. The boat 217 is made of, for example, a heat-resistant material such as quartz or SiC. For example, a heat insulating plate 218 that is formed of a heat-resistant material such as quartz or SiC is supported on a lower portion of the boat 217 in multiple stages.

(Heat Insulating Plate)

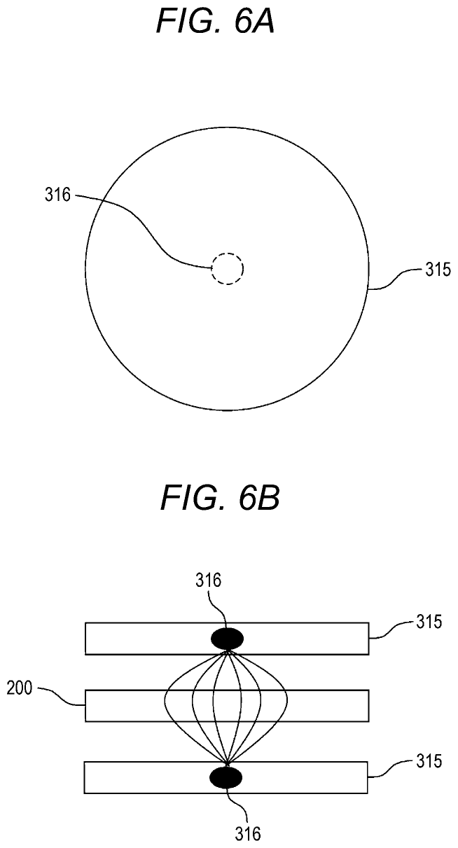

As illustrated in FIG. 6A, the heat insulating plate 315 includes a magnet 316 serving as a magnetic field generator (a magnetic field generator) that is imbedded in the center and generates a magnetic field. In addition, the magnet 316 has a Curie temperature higher than a film-forming temperature (a processing temperature). In addition, the heat insulating plate 315 is configured by a plate in the shape of a disk having the same diameter as that of the wafer 200. In addition, the heat insulating plate 315, for example, is formed of an insulating material (an insulating member) such as quartz or SiC. Since the magnet 316 is embedded in the heat insulating plate 315, the contamination inside the process chamber 201 due to the magnet 316 can be prevented. As illustrated in FIG. 6B, the magnet 316 is provided in the center of the heat insulating plate 315, and the wafer 200 and the heat insulating plate 315 are alternately disposed on the boat 217 to interpose the wafer 200 between the heat insulating plates 315, and thus, the magnetic field is generated in the vicinity of the center of the wafer 200, and a change occurs in a plasma distribution. By controlling the magnetic field, it is also possible to supply radicals (active species) that are generated from the plasma to the center of the wafer 200. Accordingly, it is possible to suppress a variation in film quality between an edge of the wafer 200 and the center of the wafer 200. The plurality of wafers 200 may be interposed between the heat insulating plates 315.

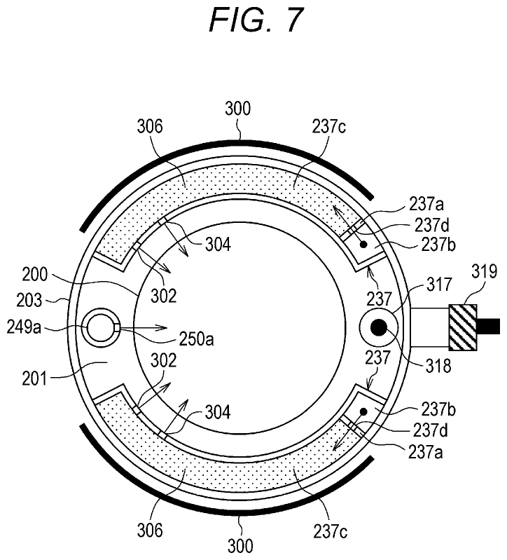

Instead of the heat insulating plate 315 including the magnet 316, as illustrated in FIG. 7, a magnetic field generator (a magnetic field generator) configured by a magnetic metal 318 that is provided inside the process chamber 201, a ferromagnet 319 that is provided outside the process chamber 201 and is connected to the magnetic metal 318 may be provided. The magnetic metal 318, for example, is SUS 430 or the like. The ferromagnet 319, for example, is an electromagnet or a neodymium magnet having an intense magnetic field. The ferromagnet 319 has low heat resistance, and thus, is provided outside the process chamber 201. In addition, the magnetic metal 318 has the Curie temperature higher than the film-forming temperature (the processing temperature). The magnetic metal 318 is provided along the vertical direction (the direction in which the wafers 200 are stacked), and is covered with a protective tube 317. The protective tube 317, for example, is a quartz tube. Since the magnetic metal 318 is covered with the protective tube 317, the contamination inside the process chamber 201 due to the magnetic metal 318 can be prevented. The magnetic metal 318 is provided at a position facing a position at which the plasma generator is provided. That is, the magnetic metal 318 is provided at a position facing the gas supply ports 302 and 304 that are formed on the arc-shaped wall surface of the buffer structure 237 and supply gas. Accordingly, it is also possible to supply the radicals (the active species) that are generated from the plasma to the center of the wafer 200, and to suppress a variation in the film quality between the edge of the wafer 200 and the center of the wafer 200. In addition, in a case where the exhauster is disposed at the position facing the gas supply ports 302 and 304, the magnetic metal 318 is disposed to avoid the exhauster.

As illustrated in FIG. 1, a temperature sensor 263 serving as a temperature detector is installed inside the reaction tube 203. By regulating an energization condition with respect to the heater 207 on the basis of temperature information detected by the temperature sensor 263, a temperature inside the process chamber 201 is set to a desired temperature distribution. The temperature sensor 263 is provided along the inner wall of the reaction tube 203, as with the nozzle 249a.

(Control Device)

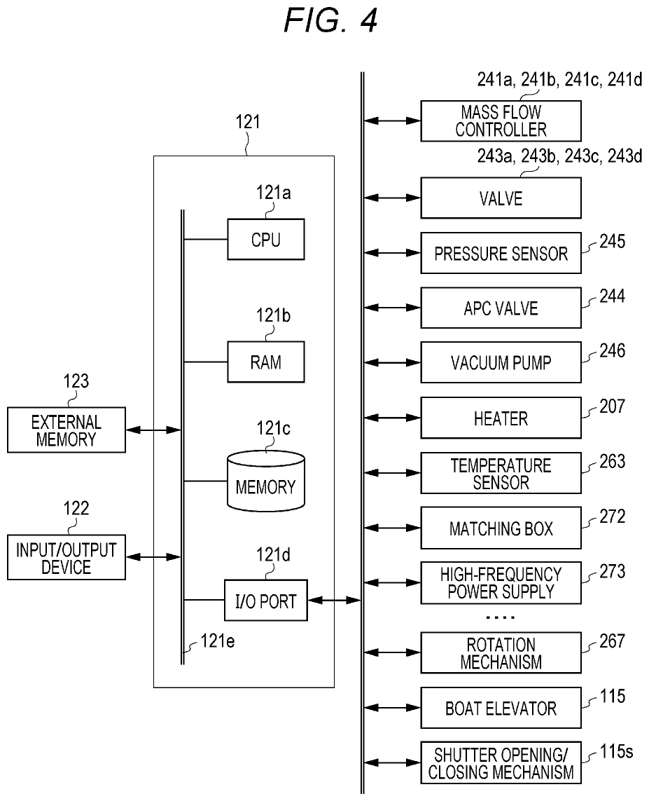

Next, a control device will be described by using FIG. 4. As illustrated in FIG. 4, a controller 121 that is a controller (the control device) is configured as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An input/output device 122 configured as, for example, a touch panel is connected to the controller 121.

The memory 121c is configured by, for example, a flash memory, a hard disk drive (HDD), and the like. In the memory 121c, a control program that controls an operation of the substrate processing apparatus, a process recipe in which a procedure, a condition, or the like for film-forming processing, described below, is described, and the like are stored to be readable. The process recipe is combined to allow the controller 121 to execute each procedure in various processing (the film-forming processing) described below such that a predetermined result can be obtained, and functions as a program. Hereinafter, the process recipe, the control program, and the like are also collectively and simply referred to as a program. The process recipe is also simply referred to as a recipe. In the present specification, the term “program” may include only the recipe alone, only the control program alone, or both. The RAM 121b is configured as a memory area (work area) in which programs, data, and the like read by the CPU 121a are temporarily stored.

The I/O port 121d is connected to the MFCs 241a to 241d, the valves 243a to 243d, the pressure sensor 245, the APC valve 244, the vacuum pump 246, the heater 207, the temperature sensor 263, the matching box 272, the high-frequency power supply 273, the rotation mechanism 267, the boat elevator 115, the shutter opening/closing mechanism 115s, and the like, described above.

The CPU 121a is configured to read the control program from the memory 121c and executes the control program, and to read the recipe from the memory 121c in response to an input or the like of an operation command from the input/output device 122. The CPU 121a is configured to control the rotation mechanism 267, a flow rate regulating operation of various gas by the MFCs 241a to 241d, an opening/closing operation of the valves 243a to 243d, a regulating operation of the high-frequency power supply 273 based on impedance monitoring, an opening/closing operation of the APC valve 244, a pressure regulating operation by the APC valve 244 based on the pressure sensor 245, activation and stop of the vacuum pump 246, a temperature regulating operation of the heater 207 based on the temperature sensor 263, a forward/reverse rotation of the boat 217 by the rotation mechanism 267, a rotation angle and rotation rate adjusting operation, a lifting operation of the boat 217 by the boat elevator 115, plasma generation by the high-frequency power supply 273 and the external electrode 300, and the like.

The controller 121 can be configured by installing the above-described program stored in an external memory (for example, a magnetic disk such as a hard disk, an optical disk such as a CD, a magneto-optical disk such as an MO, or a semiconductor memory such as a USB memory) 123 in a computer. The memory 121c and the external memory 123 are configured as computer-readable recording media. Hereinafter, these are collectively and simply referred to as a recording medium. In the present specification, the term “recording medium” may include only the memory 121c alone, only the external memory 123 alone, or both. Note that the program may be provided to the computer by using a communication means such as the Internet or a dedicated line without using the external memory 123.

(2) Substrate Processing Step

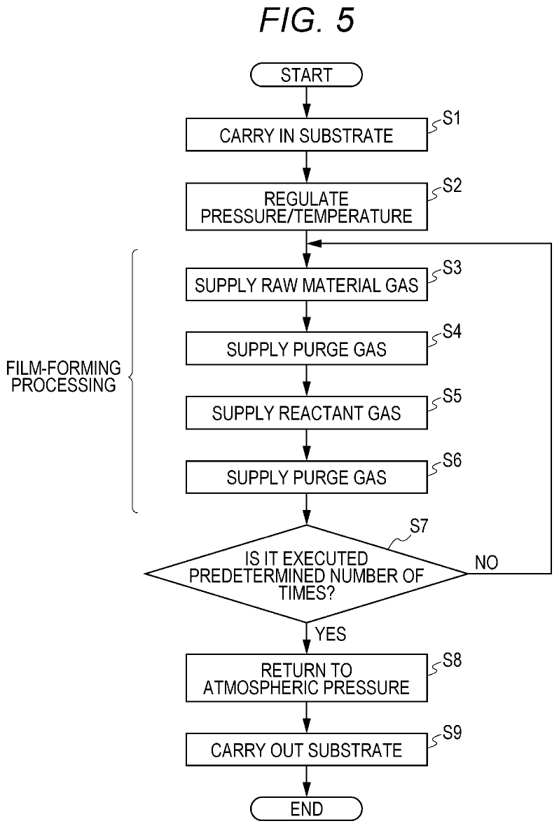

Next, as one step of a manufacturing step of a semiconductor device using the substrate processing apparatus, a step of forming a thin film on the wafer 200 will be described with reference to FIG. 5. In the following description, an operation of each constituent of the substrate processing apparatus is controlled by the controller 121.

Here, an example of forming a silicon nitride film (a SiN film) on the wafer 200 as a film containing Si and N by performing a step of supplying DCS gas as the raw material gas, and a step of supplying NH3 gas subjected to plasma excitation as the reactant gas non-simultaneously, that is, predetermined times (one or more times) without synchronizing the steps will be described. In addition, for example, a predetermined film may be formed in advance on the wafer 200. In addition, a predetermined pattern may be formed in advance on the wafer 200 or the predetermined film.

In the present specification, a process flow of the film-forming processing illustrated in FIG. 5, for convenience sake, is as follows.

(DCS→NH3*)×n⇒SiN

In the present specification, the term “wafer” means a wafer itself, or a laminate of a wafer and a predetermined layer or film formed on the surface of the wafer in some cases. In the present specification, the term “surface of a wafer” means a surface of a wafer itself, or a surface of a predetermined layer or the like formed on the wafer in some cases. In this specification, the term “form a predetermined layer on a wafer” means that a predetermined layer is formed directly on the surface of the wafer itself or that a predetermined layer is formed on a layer or the like formed on the wafer. The use of the term “substrate” in this specification is synonymous with the use of the term “wafer”.

(Carrying-In Step: S1)

In a case where the plurality of wafers 200 are charged in the boat 217 (wafer charging), the shutter 219s is moved by the shutter opening/closing mechanism 115s, and the lower end opening of the manifold 209 is opened (shutter opening). After that, as illustrated in FIG. 1, the boat 217 on which the plurality of wafers 200 are supported is lifted up by the boat elevator 115 and is carried into the process chamber 201 (boat loading). In this state, the seal cap 219 seals the lower end of the manifold 209 through the O-ring 220b.

(Pressure/Temperature Regulating Step: S2)

The inside of the process chamber 201, that is, a space in which the wafer 200 exists is subjected to vacuum exhaust (decompression-exhaust) by the vacuum pump 246 to have a desired pressure (degree of vacuum). At this time, the pressure in the process chamber 201 is measured by the pressure sensor 245, and the APC valve 244 is feedback-controlled based on the measured pressure information. The vacuum pump 246 maintains a state of being constantly operated at least until a film-forming step described below is ended.

In addition, the wafer 200 inside the process chamber 201 is heated by the heater 207 to have a desired temperature. At this time, the supply of power to the heater 207 is feedback-controlled based on the temperature information detected by the temperature sensor 263 so that the inside of the process chamber 201 has a desired temperature distribution. The heating of the inside of the process chamber 201 by the heater 207 is continuously performed at least until the film-forming step described below is ended. Here, in a case where the film-forming step is performed under a temperature condition of a room temperature or lower, the inside of the process chamber 201 may not be heated by the heater 207. In addition, in the case of performing processing at such a temperature, the heater 207 may not be used, and the heater 207 may not be installed in the substrate processing apparatus. In this case, it is possible to simplify the configuration of the substrate processing apparatus.

Subsequently, the rotation of the boat 217 and the wafer 200 by the rotation mechanism 267 is started. The rotation of the boat 217 and the wafer 200 by the rotation mechanism 267 is continuously performed at least until the film-forming step is ended.

(Raw Material Gas Supplying Step: S3 and S4)

In step S3, the DCS gas is supplied to the wafer 200 inside the process chamber 201. The valve 243a is opened, and the DCS gas flows into the gas supply pipe 232a. A flow rate of the DCS gas is regulated by the MFC 241a, and the DCS gas is supplied into the process chamber 201 from the gas supply hole 250a through the nozzle 249a, and is exhausted from the exhaust pipe 231. The valve 243c is opened at the same time, and the N2 gas flows into the gas supply pipe 232c. The flow rate of the N2 gas is regulated by the MFC 241c, and the N2 gas is supplied into the process chamber 201 together with the DCS gas, and is exhausted from the exhaust pipe 231.

In addition, in order to suppress the infiltration of the DCS gas into the piping 249b, the valve 243d is opened, and the N2 gas flows into the gas supply pipe 232d. The N2 gas is supplied into the process chamber 201 through the gas supply pipe 232b and the piping 249b, and is exhausted from the exhaust pipe 231.

A supply flow rate of the DCS gas that is controlled by the MFC 241a, for example, is a flow rate in a range of 1 sccm or more and 6000 sccm or less, preferably in a range of 3000 sccm or more and 5000 sccm or less. A supply flow rate of the N2 gas that is controlled by each of the MFCs 241c and 241d, for example, is set to a flow rate in a range of 100 sccm or more and 10000 sccm or less. The pressure inside the process chamber 201, for example, is a pressure in a range of 1 Pa or more and 2666 Pa or less, and preferably in a range of 665 Pa or more and 1333 Pa. A time for exposing the wafer 200 to the DCS gas, for example, is a time of approximately 20 seconds per one cycle. Additionally, the time for exposing the wafer 200 to the DCS gas is different in accordance with the thickness of the film.

The temperature of the heater 207, is set to a temperature at which the temperature of the wafer 200, for example, is a temperature in a range of 0° C. or higher and 700° C. or lower, preferably in a range of a room temperature (25° C.) or higher and 550° C. or lower, and more preferably in a range of 40° C. or higher and 500° C. or lower. As with this embodiment, by setting the temperature of the wafer 200 to 700° C. or lower, further to 550° C. or lower, and further to 500° C. or lower, it is possible to reduce the amount of heat to be applied to the wafer 200, and it is possible to successfully control a heat history received by the wafer 200.

By supplying the DCS gas to the wafer 200 under the condition described above, a Si-containing layer is formed on the wafer 200 (a base film of the surface). The Si-containing layer may contain Cl or H, in addition to a Si layer. The Si-containing layer is formed on the outermost surface of the wafer 200 by physical adsorption of the DCS, chemical adsorption of a substance obtained by decomposing a part of the DCS, deposition of Si due to heat decomposition of the DCS, or the like. That is, the Si-containing layer may be an adsorption layer (a physical adsorption layer or a chemical adsorption layer) of the substance obtained by decomposing the DCS or a part of the DCS, or may be a deposition layer of Si (the Si layer).

After the Si-containing layer is formed, the valve 243a is opened, and the supply of the DCS gas into the process chamber 201 is stopped. The APC valve 244 is set in an open state, the inside of the process chamber 201 is subjected to vacuum exhaust by the vacuum pump 246, and the unreacted DCS gas that remains inside the process chamber 201 or the DCS gas after contributing to the formation of the Si-containing layer, a reaction byproduct, or the like is removed from the inside of the process chamber 201 (S4). In addition, the valves 243c and 243d are set in an open state, and the supply of the N2 gas into the process chamber 201 is maintained. The N2 gas functions as purge gas. Furthermore, this step S4 may be omitted.

As the raw material gas, various aminosilane raw material gas such as tetrakisdimethyl aminosilane (Si[N(CH3)2]4, Abbreviated Name: 4DMAS) gas, trisdimethyl aminosilane (Si[N(CH3)2]3H, Abbreviated Name: 3DMAS) gas, bisdimethyl aminosilane (Si[N(CH3)2]2H2, Abbreviated Name: BDMAS) gas, bisdiethyl aminosilane (Si[N(C2H5)2]2H2, Abbreviated Name: BDEAS), bistertiary butyl am inosilane (SiH2[NH(C4H9)]2, Abbreviated Name: BTBAS) gas, dimethyl aminosilane (DMAS) gas, diethyl aminosilane (DEAS) gas, dipropyl aminosilane (DPAS) gas, diisopropyl aminosilane (DIPAS) gas, butyl aminosilane (BAS) gas, and hexamethyl disilazane (HMDS) gas, inorganic halosilane raw material gas such as monochlorosilane (SiH3Cl, Abbreviated Name: MCS) gas, trichlorosilane (SiHCl3, Abbreviated Name: TCS) gas, tetrachlorosilane (SiCl4, Abbreviated Name: STC) gas, hexachlorodisilane (Si2Cl6, Abbreviated Name: HCDS) gas, and octachlorotrisilane (Si3Cl8, Abbreviated Name: OCTS) gas, and non-halogen group-containing inorganic silane raw material gas such as monosilane (SiH4, Abbreviated Name: MS) gas, disilane (Si2H6, Abbreviated Name: DS) gas, and trisilane (Si3H8, Abbreviated Name: TS) gas can be preferably used instead of the DCS gas.

As the inert gas, rare gas such as Ar gas, He gas, Ne gas, and Xe gas can be used instead of the N2 gas.

(Reactant Gas Supplying Step: S5 and S6)

After the film-forming processing is ended, plasma-excited NH3 gas serving as reactant gas is supplied to the wafer 200 inside the process chamber 201 (S5).

In this step, opening/closing control of valves 243b to 243d is performed in the same procedure as that of the opening/closing control of the valves 243a, 243c, and 243d in step S3. A flow rate of the NH3 gas is regulated by the MFC 241b, and is supplied into the buffer chamber 237c through the piping 249b. In this case, high-frequency power is supplied to the external electrode 300. The NH3 gas supplied into the buffer chamber 237c is excited into a plasma state (activated with plasma), is supplied into the process chamber 201 as active species (NH3*), and is exhausted from the exhaust pipe 231.

A supply flow rate of the NH3 gas that is controlled by the MFC 241b, for example, is a flow rate in a range of 100 sccm or more and 10000 sccm or less, and preferably in a range of 1000 sccm or more and 2000 sccm or less. The high-frequency power to be applied to the external electrode 300, for example, is power in a range of 50 W or more and 600 W or less. The pressure inside the process chamber 201, for example, is a pressure in a range of 1 Pa or more and 500 Pa or less. By using the plasma, it is possible to activate the NH3 gas even in a case where the pressure inside the process chamber 201 is at a comparatively low pressure zone. A time for supplying the active species obtained by the plasma excitation of the NH3 gas to the wafer 200, that is, a gas supply time (an exposure time), for example, is a time in a range of 1 second or longer and 180 seconds or shorter, preferably in a range of 1 second or longer and 60 seconds or shorter. Other processing conditions are the same as the processing condition of S3 described above.

By supplying the NH3 gas to the wafer 200 under the condition described above, the Si-containing layer formed on the wafer 200 is subjected to plasma nitridation. By the energy of the plasma-excited NH3 gas, a Si—Cl bond and a Si—H bond of the Si-containing layer are cut. Cl and H separated from Si are desorbed from the Si-containing layer. Si in the Si-containing layer that has a dangling bond (a dangling-bond) due to the desorption of Cl or the like is bonded to N contained in the NH3 gas, and thus, a Si—N bond is formed. As such a reaction progresses, the Si-containing layer is changed (modified) to a layer containing S and N, that is, a silicon nitride layer (a SiN layer).

Note that, in order to modify the Si-containing layer to the SiN layer, there is a need to supply the plasma-excited NH3 gas. This is because even in a case where the NH3 gas is supplied under a non-plasma atmosphere, energy that is needed to nitride the Si-containing layer is insufficient at the temperature zone described above, and it is difficult to sufficiently desorb Cl or H from the Si-containing layer, or to sufficiently nitride the Si-containing layer to increase the Si—N bond.

After the Si-containing layer is changed to the SiN layer, the valve 243b is opened, and the supply of the NH3 gas is stopped. In addition, the supply of the high-frequency power to the external electrode 300 is stopped. According to the same processing procedure and the same processing condition as those of step S4, the NH3 gas remaining inside the process chamber 201, or the reaction byproduct is removed from the inside of the process chamber 201 (S6). Furthermore, this step S6 may be omitted.

As a nitriding agent, that is, an N-containing gas to be plasma-excited, diazene (N2H2) gas, hydrazine (N2H4) gas, N3H8 gas, and the like may be used instead of the NH3 gas.

As the inert gas, for example, various rare gas exemplified in step S4 can be used instead of the N2 gas.

(Predetermined Number of Times of Execution: S7)

Performing S3, S4, S5, and S6 described above in this order non-simultaneously, that is, without synchronizing the steps is set to one cycle, and the cycle is performed a predetermined number of times (n times), that is, one or more times (S7), and thus, the SiN film having a predetermined composition and a predetermined thickness of the film can be formed on the wafer 200. It is preferable that the cycle described above is performed a predetermined number of times. That is, it is preferable that the thickness of the SiN layer to be formed per one cycle is set to be smaller than a desired thickness of the film, and the cycle described above is performed a predetermined number of times until the thickness of the film of the SiN film to be formed by stacking the SiN layer is a desired thickness of the film.

(Step of Returning to Atmospheric Pressure: S8)

After the film-forming processing described above is completed, the N2 gas serving as the inert gas is supplied into the process chamber 201 from each of the gas supply pipes 232c and 232d, and is exhausted from the exhaust pipe 231. Accordingly, the inside of the process chamber 201 is purged with the inert gas, and the gas remaining inside the process chamber 201, or the like is removed from the inside of the process chamber 201 (inert gas purge). After that, the atmosphere inside the process chamber 201 is replaced with the inert gas (inert gas replacement), and the pressure inside the process chamber 201 is returned to a normal pressure (S8).

(Carrying-Out Step: S9)

After that, the seal cap 219 is lifted down by the boat elevator 115, the lower end of the manifold 209 is opened, and the processed wafer 200 is carried out to the outside of the reaction tube 203 from the lower end of the manifold 209 in a state of being supported on the boat 217 (boat unloading) (S9). After the boat is unloaded, the shutter 219s is moved, and the lower end open of the manifold 209 is sealed with the shutter 219s through the O-ring 220c (shutter closing). The processed wafer 200 is carried out to the outside of the reaction tube 203, and then, is taken out by the boat 217 (wafer discharge). Additionally, after the wafer is discharged, the empty boat 217 may be carried into the process chamber 201.

### (3) Effects of this Embodiment

According to this embodiment, one or a plurality of effects described below can be obtained.

(a) The plasma reaches the center of the wafer by forming and using the magnetic field inside the reaction tube (the process chamber), and a plasma density in the center of the wafer is improved.

(b) The plasma or the active species reach the center of the wafer, and thus, a variation in the film quality between the edge of the wafer and the center of the wafer is decreased, and the uniformity of the film quality inside the wafer surface is improved.

In the above, the embodiment of the present disclosure has been described in detail. However, the present disclosure is not limited to the above-described embodiment, and various modifications can be made without departing from the gist thereof.

For example, in the embodiment described above, an example of supplying the reactant gas after the raw material is supplied has been described. The present disclosure is not limited to such an aspect, and a supply order of the raw material and the reactant gas may be reversed. That is, the raw material may be supplied after the reactant gas is supplied. By changing the supply order, it is possible to change film quality or a composition ratio of a film to be formed.

In the embodiment described above or the like, an example of forming the SiN film on the wafer 200 has been described. The present disclosure is not limited to such an aspect, and can also be preferably applied to a case where a Si-based oxide film such as a silicon oxide film (a SiO film), a silicon oxycarbide film (a SiOC film), a silicon oxycarbonitride film (a SiOCN film), and a silicon oxynitride film (a SiON film) is formed on the wafer 200 or a case where a Si-based nitride film such as a silicon carbonitride film (a SiCN film), a silicon boronitride film (a SiBN film), and a silicon borocarbonitride film (a SiBCN film) is formed on the wafer 200. In such a case, as the reactant gas, a C-containing gas such as C3H6, an N-containing gas such as NH3, and B-containing gas such as BCl3 can be used instead of O-containing gas.

In addition, the present disclosure can also be preferably applied to a case where an oxide film or a nitride film containing a metal element such as titanium (Ti), zirconium (Zr), hafnium (Hf), tantalum (Ta), niobium (Nb), aluminum (Al), molybdenum (Mo), and tungsten (W), that is, a metal-based oxide film or a metal-based nitride film is formed on the wafer 200. That is, the present disclosure can also be preferably applied to a case where a TiO film, a TiN film, a TiOC film, a TiOCN film, a TiON film, a TiBN film, a TiBCN film, a ZrO film, a ZrN film, a ZrOC film, a ZrOCN film, a ZrON film, a ZrBN film, a ZrBCN film, a HfO film, a HfN film, a HfOC film, a HfOCN film, a HfON film, a HfBN film, a HfBCN film, a TaO film, a TaOC film, a TaOCN film, a TaON film, a TaBN film, a TaBCN film, a NbO film, a NbN film, a NbOC film, a NbOCN film, a NbON film, a NbBN film, a NbBCN film, an AlO film, an AlN film, an AIOC film, an AIOCN film, an AION film, an AIBN film, an AIBCN film, a MoO film, a MoN film, a MoOC film, a MoOCN film, a MoON film, a MoBN film, a MoBCN film, a WO film, a WN film, a WOC film, a WOCN film, a WON film, a MWBN film, a WBCN film, or the like is formed on the wafer 200.

In such a case, for example, as the raw material gas, tetrakis(dimethylamino)titanium (Ti[N(CH3)2]4, Abbreviated Name: TDMAT) gas, tetrakis(ethylmethylamino)hafnium (Hf[N(C2H5)(CH3)]4, Abbreviated Name: TEMAH) gas, tetrakis(ethylmethylamino)zirconium (Zr[N(C2H5)(CH3)]4, Abbreviated Name: TEMAZ) gas, trimethyl aluminum (Al(CH3)3, Abbreviated Name: TMA) gas, titanium tetrachloride (TiCl4) gas, hafnium tetrachloride (HfCl4) gas, and the like can be used. As the reactant gas, the reactant gas described above can be used.

That is, the present disclosure can be preferably applied to the case of forming a half metal-based film containing a half metal element, or a metal-based film containing a metal element. A processing procedure and a processing condition of film-forming processing of such a film can be the same processing procedure and the same processing condition as those of the film-forming processing described in the embodiment described above or modification examples. Even in such a case, the same effects as those of the embodiment described above or the modification examples can be obtained.

It is preferable that the recipe used in the film-forming processing is individually prepared in accordance with the processing contents, and is stored in the memory 121c through a telecommunication line or the external memory 123. When various processing is started, it is preferable that the CPU 121a suitably selects an appropriate recipe from a plurality of recipes stored in the memory 121c, in accordance with the processing contents. Accordingly, thin films with various film types, composition ratios, film qualities, and thicknesses of the films can be generally and reproducibly formed by one substrate processing apparatus. In addition, it is possible to reduce a burden on an operator, and it is possible to quickly start various processing while avoiding an operation error.

The above-described recipe is not limited to a newly created one, and may be prepared by changing the existing recipe already installed in the substrate processing apparatus, for example. In the case of changing the recipe, the changed recipe may be installed in the substrate processing apparatus through a telecommunication line or a recording medium in which the recipe is recorded. In addition, the input/output device 122 of the existing substrate processing apparatus may be operated, and the existing recipe previously installed in the substrate processing apparatus may be directly changed.

According to the present disclosure, it is possible to provide a technique that is capable of supplying plasma active species gas generated at a high efficiency to a substrate.

1. A substrate processing apparatus, comprising:
a process chamber in which a substrate is processed;
a substrate retainer on which a plurality of substrates are stacked in multiple stages;
a plasma generator configured to generate plasma inside the process chamber; and
a magnetic field generator configured to generate a magnetic field inside the process chamber.

2. The substrate processing apparatus according to claim 1,
wherein the magnetic field generator generates the magnetic field in the vicinity of a center of the substrate.

3. The substrate processing apparatus according to claim 2,
wherein the plurality of substrates, and a heat insulating plate in which the magnetic field generator is provided on a center are stacked on the substrate retainer.

4. The substrate processing apparatus according to claim 3,
wherein the magnetic field generator is embedded in the heat insulating plate.

5. The substrate processing apparatus according to claim 4,
wherein the substrate and the heat insulating plate are alternately disposed on the substrate retainer.

6. The substrate processing apparatus according to claim 3,
wherein the heat insulating plate is retained on the substrate retainer such that the plurality of substrates are interposed.

7. The substrate processing apparatus according to claim 3,
wherein the heat insulating plate is composed of an insulating material.

8. The substrate processing apparatus according to claim 3,
wherein the magnetic field generator is composed of a magnet with a Curie temperature higher than a processing temperature of the substrate.

9. The substrate processing apparatus according to claim 1,
wherein the plasma generator is provided outside the process chamber.

10. The substrate processing apparatus according to claim 1,
wherein the magnetic field generator is composed of a magnetic metal provided inside the process chamber, and a ferromagnet connected to the magnetic metal.

11. The substrate processing apparatus according to claim 10,
wherein the magnetic metal is provided in a direction in which the substrates are stacked.

12. The substrate processing apparatus according to claim 10,
wherein the magnetic metal is covered with a protective tube.

13. The substrate processing apparatus according to claim 10,
wherein the magnetic field generator is provided at a position facing a position at which the plasma generator is provided.

14. The substrate processing apparatus according to claim 1, further comprising a heater configured to heat the substrate.

15. A method of processing a substrate, comprising:
carrying a substrate into a process chamber of a substrate processing apparatus including the process chamber in which the substrate is processed, a substrate retainer on which a plurality of substrates are stacked in multiple stages, a plasma generator configured to generate plasma inside the process chamber, and a magnetic field generator configured to generate a magnetic field inside the process chamber; and
generating the plasma inside the process chamber.

16. A method of manufacturing a semiconductor device comprising the method according to claim 15.

17. A non-transitory computer-readable recording medium storing a program that causes, by a computer, a substrate processing apparatus to perform:
carrying a substrate into a process chamber of the substrate processing apparatus including the process chamber in which the substrate is processed, a substrate retainer on which a plurality of substrates are stacked in multiple stages, a plasma generator configured to generate plasma inside the process chamber, and a magnetic field generator configured to generate a magnetic field inside the process chamber; and
generating the plasma inside the process chamber.
